(19) United States
(12) Patent Application Publication
(10) Pub. No.: US 2025/0046667 A1
(43) Pub. Date: Feb. 6, 2025

(54) Heat Dissipating Structure and Methods of Forming The Same

(71) Applicant: Taiwan Semiconductor Manufacturing Co., Ltd., Hsinchu (TW)

(72) Inventors: Tsung-Chieh Hsiao, Shetou Township (TW); Ke-Gang Wen, Hsinchu (TW); Chih-Pin Chiu, Hsinchu (TW); Hsin-Feng Chen, Yilan City (TW); Yu-Bey Wu, Hsinchu (TW); Liang-Wei Wang, Hsinchu (TW); Dian-Hau Chen, Hsinchu (TW)

(21) Appl. No.: 18/482,217

(22) Filed: Oct. 6, 2023

Related U.S. Application Data
(60) Provisional application No. 63/517,378, filed on Aug. 3, 2023.

(51) Int. Cl. H01L 23/367; H01L 23/00; H01L 25/065

(52) U.S. Cl. CPC H01L 23/367; H01L 24/27; H01L 24/29; H01L 24/32; H01L 24/83; H01L 25/0657; H01L 24/05; H01L 24/06; H01L 24/08; H01L 24/80; H01L 24/94; H01L 2224/0557; H01L 2224/05571; H01L 2224/05573; H01L 2224/06181; H01L 2224/08145; H01L 2224/2741; H01L 2224/29021; H01L 2224/29025; H01L 2224/2929; H01L 2224/29386; H01L 2224/29393; H01L 2224/32245; H01L 2224/80357; H01L 2224/80895; H01L 2224/80896; H01L 2224/83191; H01L 2224/83855; H01L 2224/94; H01L 2225/06565; H01L 2225/06589; H01L 2924/01006; H01L 2924/0503; H01L 2924/05032; H01L 2924/0532; H01L 2924/0543; H01L 2924/0665

(57) ABSTRACT

A method includes forming a device die including forming integrated circuits on a semiconductor substrate; and forming a thermally conductive pillar extending into the semiconductor substrate. A cooling medium is attached over and contacting the semiconductor substrate to form a package, wherein the cooling medium is thermally coupled to the thermally conductive pillar.

### PRIORITY CLAIM AND CROSS-REFERENCE

This application claims the benefit of the following provisionally filed U.S. Patent application: Application No. 63/517,378, filed on Aug. 3, 2023, and entitled “Semiconductor Device and Method of Manufacturing the Same,” which application is hereby incorporated herein by reference.

### BACKGROUND

With the increasing higher degree of integration level of integrated circuits, more and more devices are compacted into smaller areas. In the meantime, to improve the speed of the integrated circuits, the driving currents of the integrated circuits also become higher. The heat dissipation of the integrated circuits thus become more demanding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2, 3 and 4 illustrate the cross-sectional views of intermediate stages in the formation of a package including thermally conductive pillars in accordance with some embodiments.

FIGS. 5, 6, 7A, 7B, 7C, 8 and 9 illustrate the cross-sectional views of intermediate stages in the formation of a package including thermally conductive pillars in accordance with some embodiments.

FIGS. 10A, 10B, 10C, 10D, and 10E illustrate the view of a portion of a package and the corresponding thermally conductive pillars in accordance with some embodiments.

FIGS. 11A, 11B, 11C, and 11D illustrate the views of a portion of a package and the corresponding thermally conductive pillars in accordance with some embodiments.

FIGS. 12, 13A, and 13B illustrate the views of packages and a corresponding thermally conductive pillar in accordance with some embodiments.

FIGS. 14A, 14B, 14C, 14D, and 14E illustrate the top views of thermally conductive pillars in accordance with some embodiments.

FIG. 15 illustrates a process flow for forming a package including thermally conductive pillars in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A heat-dissipating structure and the method of forming the same are provided. In accordance with some embodiments of the present disclosure, thermally conductive pillars are formed to extend into a semiconductor substrate. The thermally conductive pillars comprise thermally conductive materials, which have better thermal conducting ability than silicon. The thermally conductive pillars may penetrate through the semiconductor substrates of the device dies, so that it may conduct the heat in the device dies away and to a heat spreader or a heat sink. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

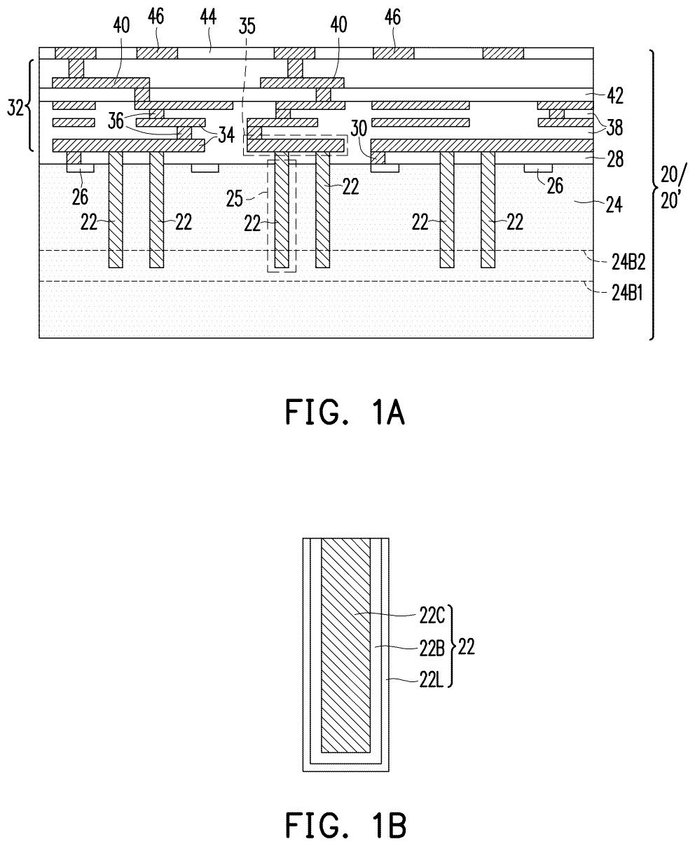

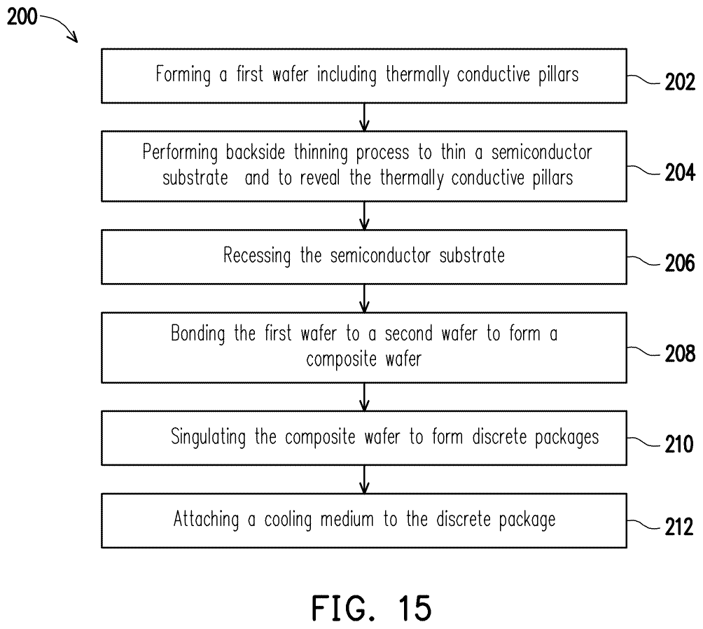

FIGS. 1A, 1B, and 2-4 illustrate the cross-sectional views of intermediate stages in the formation of a package in accordance with some embodiments of the present disclosure. This process is also referred to as a pillar-first process since thermally conductive pillars are formed before the thinning of semiconductor substrate 24. The corresponding processes are also reflected schematically in the process flow shown in FIG. 15.

FIG. 1 illustrates the cross-sectional view in the formation of package component 20. The respective process is illustrated as process 202 in the process flow 200 as shown in FIG. 15. In accordance with some embodiments, package component 20 is or comprises a device wafer including active devices and possibly passive devices, which are represented as integrated circuit devices 26. Package component 20 may include a plurality of dies 20′ therein, with the details of one of dies 20′ being illustrated. In accordance with alternative embodiments, package component 20 is or comprises a package such as an Integrated Fan-Out (InFO) Package. For example, package component 20 may be a reconstructed wafer, which includes device dies and/or a wafer(s) bonded together, and possible encapsulant(s) such as a molding compound.

In subsequent discussion, a device wafer is used as an example of package component 20, and package component 20 may also be referred to as wafer 20 hereinafter. The embodiments may also be applied on reconstructed wafers, discrete packages, discrete device dies, and the like.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, crystalline silicon germanium, carbon-doped silicon, a III-V compound semiconductor, or the like. Semiconductor substrate 24 may also be a bulk semiconductor substrate or a Semiconductor-On-Insulator (SOI) substrate.

In accordance with some embodiments, integrated circuit devices 26 are formed at the top surface of semiconductor substrate 24. Integrated circuit devices 26 may include Complementary Metal-Oxide Semiconductor (CMOS) transistors, resistors, capacitors, diodes, and/or the like in accordance with some embodiments. The details of integrated circuit devices 26 are not illustrated herein.

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of Phospho Silicate Glass (PSG), Boro Silicate Glass (BSG), Boron-doped Phospho Silicate Glass (BPSG), Fluorine-doped Silicate Glass (FSG), silicon oxide, silicon oxynitride, silicon nitride, or the like. ILD 28 may be formed using spin-on coating, Flowable Chemical Vapor Deposition (FCVD), Chemical Vapor Deposition (CVD), or the like.

Contact plugs 30 are formed in ILD 28, and are used to electrically connect integrated circuit devices 26 to overlying metal lines and vias. In accordance with some embodiments, contact plugs 30 are formed of or comprise a conductive material selected from tungsten, aluminum, copper, titanium, tantalum, titanium nitride, tantalum nitride, alloys therefore, and/or multi-layers thereof.

In accordance with some embodiments, thermally conductive pillars 22 are formed to extend into semiconductor substrate 24. In accordance with some embodiments, thermally conductive pillars 22 are formed at a time after ILD 28 is formed. The formation of contact plugs 30 may include etching ILD 28 and semiconductor substrate 24 to form openings, and filling the openings with thermally conductive materials. A planarization process (such as a Chemical Mechanical Polishing (CMP) process or a mechanical grinding process) may then be performed to remove excess portions of the materials filled in the openings, hence forming thermally conductive pillars 22.

It is appreciated that although FIG. 1 illustrates that the top surfaces of thermally conductive pillars 22 are at a same level as the top surfaces of conductive plugs 30, the top surfaces of thermally conductive pillars 22 may be at other levels such as at the same level as the top surfaces of the overlying metal lines or vias.

FIG. 1B illustrates a magnified view of thermally conductive pillar 22 in accordance with some embodiments. The illustrated thermally conductive pillar 22 may be obtained from the region 25 in FIG. 1. Thermally conductive pillars 22 may include a dielectric liner 22L, which is used for leakage prevention, and a core 22C, which has a thermal conductivity higher than the thermal conductivity of silicon, with the thermal conductivity of silicon being, for example, about 4 Watts/cm-K. There may be, or may not be, a barrier 22B, which also has a high thermal conductivity higher than the thermal conductivity of silicon.

Also, the thermal conductivity of dielectric liner 22L may be lower than, equal to, or greater than, the thermal conductivity of silicon. The overall thermal conductivity (the ability to conduct heat vertically) of the thermally conductive pillar 22, however, is higher than the thermal conductivity of silicon due to the higher thermal conductivity of the thermally conductive core 22C and the barrier 22B (if formed).

In accordance with some embodiments, the dielectric liner 22L is formed of or comprises silicon oxide, silicon nitride, silicon carbide, silicon oxycarbide, silicon oxynitride, silicon oxy-carbo-nitride, or the like. The barrier 22B may be formed of or comprises Ti, TiN, Ta, TaN, or the like. The thermally conductive core 22C may have the thermal conductivity higher than about 10 Watts/cm-K, higher than about 50 Watts/cm-K, or higher than about 100 Watts/cm-K. The material of thermally conductive core 22C may include copper, tungsten, silver, nickel, aluminum, or the like, or alloys thereof. In accordance with some embodiments, the thermally conductive core 22C has a thermal conductivity TC22C higher than the thermal conductive TC22B of barrier 22B. The thermal conductive TC22B may also be higher than the thermal conductive TC22CL of dielectric liner 22L.

Referring back to FIG. 1A, interconnect structure 32 is formed over ILD 28 and contact plugs 30. Interconnect structure 32 may include metal lines 34 and vias 36, which are formed in dielectric layers 38 (also referred to as Inter-metal Dielectrics (IMDs)). The metal lines at a same level are collectively referred to as a metal layer hereinafter. In accordance with some embodiments, interconnect structure 32 includes a plurality of metal layers interconnected through vias 36. Metal lines 34 and vias 36 may be formed of copper, a copper alloy, and/or another metal. In accordance with some embodiments, dielectric layers 38 are formed of low-k dielectric materials. The dielectric constants (k values) of the low-k dielectric materials may be lower than about 3.0, for example. Dielectric layers 38 may comprise a carbon-containing low-k dielectric material.

In accordance with some embodiments, the formation of metal lines 34 and vias 36 may include single damascene or dual damascene processes. In accordance with some embodiments, the formation of a bottom metal layer (including metal lines 34) may be performed through a single damascene process, which includes depositing a dielectric layer 38, etching the dielectric layer 38 to form trenches, filling the trenches with conductive materials, and then performing a planarization process such as a CMP process to remove excess portions of the conductive materials. The overlying metal lines and vias may be formed through dual damascene processes, which include forming dielectric layers, forming via openings and trenches in the dielectric layers, filling the via openings and the trenches with conductive materials, and performing planarization processes.

In accordance with some embodiments, the top ends of some or all of thermally conductive pillars 22 are in contact with metal lines 34. In accordance with some embodiments, some of thermally conductive pillars 22 may not have overlying metal lines, and the top surfaces of these thermally conductive pillars 22 are in contact with the bottom surfaces of the overlying dielectric layer 38 to form horizontal interfaces. For example, in accordance with some embodiments, the metal line 34 in region 35 may not be (or may be) formed, and hence region 35 is filled with a portion of dielectric layer 38. Accordingly, the respective underlying thermally conductive pillars 22 are not in contact with any metal line 34 in accordance with some embodiments. The respective thermally conductive pillars 22 may be electrically floating in accordance with these embodiments.

In accordance with some embodiments, thermally conductive pillars 22 are formed where the respective device die is hot, for example, with the respective parts of integrated circuit devices 26 generating most heat per unit chip area than other parts of the integrated circuit devices 26. Thermally conductive pillars 22 may be arranged as an array, a beehive pattern (hexagonal), or any other pattern, regular or irregular.

Over interconnect structure 32 may include a passivation layer 42, which may be formed of a non-low-k dielectric material, over the low-k dielectric layers. The passivation layer 42 may be formed of or comprise Undoped Silicate Glass (USG), silicon nitride, silicon oxide, or the like, or multi-layers thereof. There may also be metal pads (such as aluminum copper pads) 40, Post Passivation Interconnect (PPI), metal pads, or the like, which are referred to as conductive features.

Over metal pads 40 and interconnect structure 32, bond film 44 is deposited. The top surface of bond film 44 is coplanar. Bond film 44, when deposited, may be a blanket dielectric layer that is free from conductive features (such as conductive lines and conductive pads) therein. In accordance with some embodiments, bond film 44 may be formed of a silicon-base dielectric material, which may be formed of or comprise SiON, SiN, SiOCN, SiCN, SiOC, SiC, or the like.

Bond pads 46 are formed in bond film 44, and may have top surfaces coplanar with the top surface of bond film 44. In accordance with some embodiments, bond pads 46 are formed using a damascene process, which include etching bond film 44 to form openings, filling the openings with conductive material, and performing a planarization process.

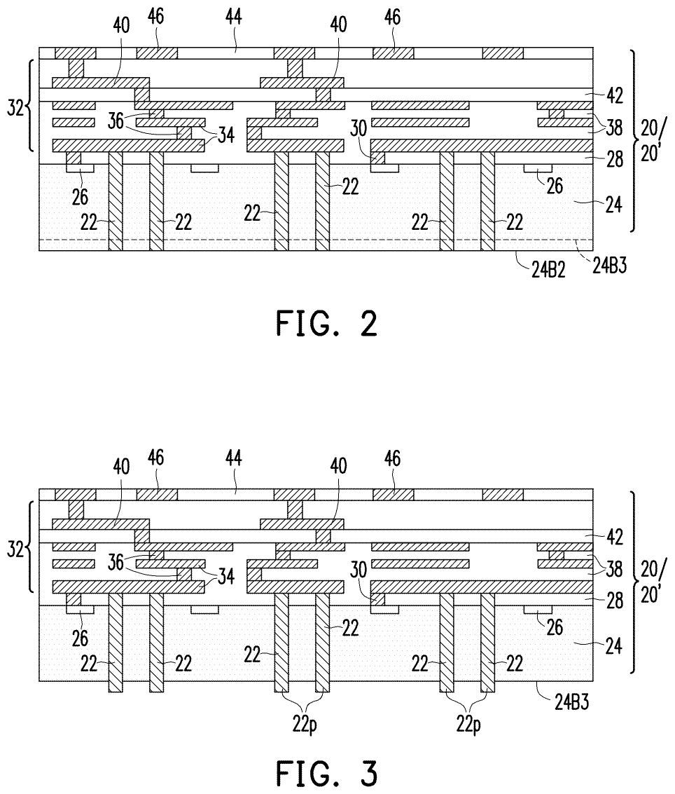

FIG. 2 illustrates a backside thinning process to thin semiconductor substrate 24 from its backside. The respective process is illustrated as process 204 in the process flow 200 as shown in FIG. 15. The backside thinning process may be performed through a CMP process or a mechanical grinding process. In accordance with some embodiments, the backside thinning process is stopped before thermally conductive pillars 22 are exposed from the backside of semiconductor substrate 24. The respective bottom surface 24B1 of semiconductor substrate 24 is illustrated in FIG. 1 as an example. In accordance with these embodiments, the backside thinning process is stopped after thermally conductive pillars 22 are exposed from the backside of semiconductor substrate 24. Some exposed portions of thermally conductive pillars 22 are also polished. The respective bottom surface 24B2 of semiconductor substrate 24 is illustrated in FIG. 2 as an example, and also illustrated in FIG. 1.

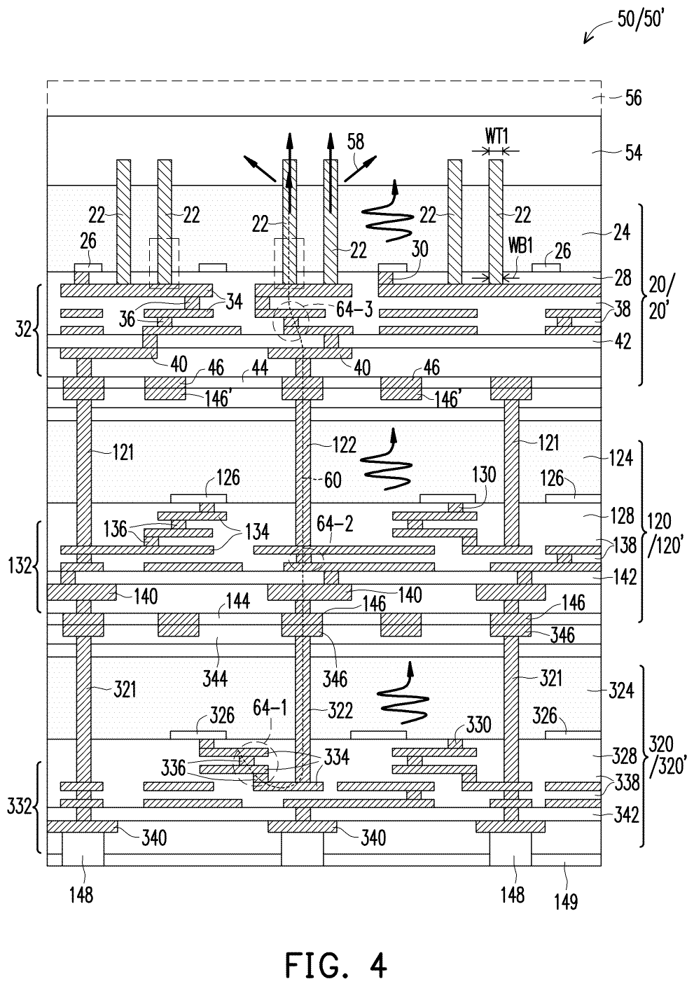

FIG. 3 illustrates the wafer 20 after a recessing process of semiconductor substrate 24 in accordance with some embodiments. The respective process is illustrated as process 206 in the process flow 200 as shown in FIG. 15. The respective back surface of semiconductor substrate 24 is denoted as 24B3, which is also illustrated in FIG. 2 in accordance with some embodiments. The recessing process may be performed through an anisotropic etching process or an isotropic etching process. The recessing is selective, so that at least the core 22C of thermally conductive pillars 22 are not recessed, and thermally conductive pillars 22 include protruding portions 22P, as shown in FIG. 3.

In accordance with some embodiments, in the recessing, the entire thermally conductive pillars 22 are not recessed, and accordingly, the portions of thermally conductive cores 22C (FIG. 1B), barriers 22B, and dielectric liners 22L in protruding portions 22P all protrude out of the back surface 24B3 of semiconductor substrate 24. In accordance with alternative embodiments, the protruding portions of dielectric liners 22L are also recessed, so that the bottom ends of the dielectric liners 22L are at the same level as back surface 24B3. The recessing of dielectric liners 22L may be performed in the same recessing process of semiconductor substrate 24, or may be performed in a separate etching process (using a different etching chemical) than the recessing of semiconductor substrate 24.

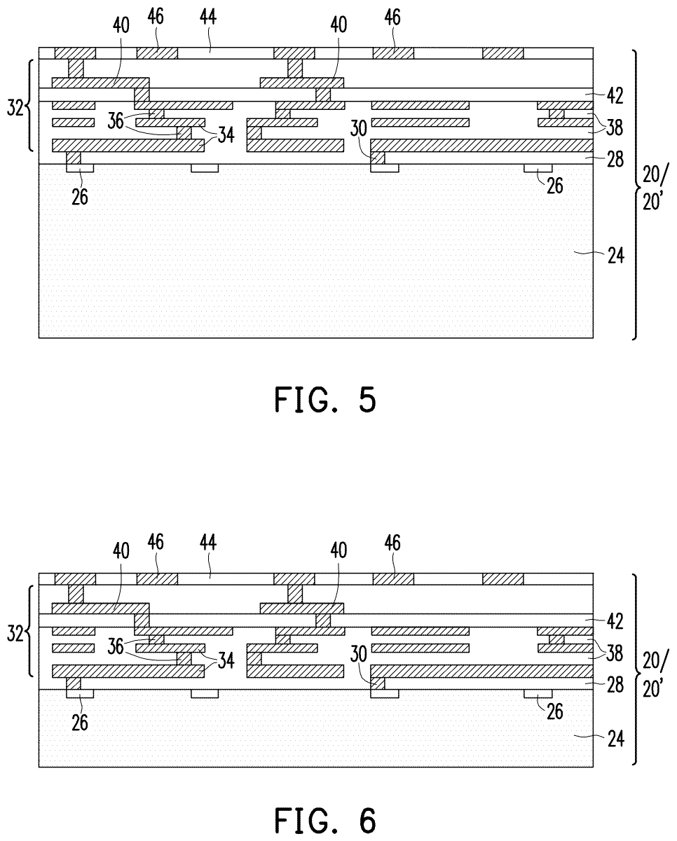

In accordance with yet alternative embodiments, barrier 22B may be recessed, or may not be recessed. When barrier 22B is recessed, it may be recessed in the same recessing process as, or a different recessing process than, the recessing of semiconductor substrate 24. When barrier 22B is recessed, it may be recessed in the same recessing process as, or a different recessing process than, the recessing of dielectric liner 22L. Since the thermal conductivity of thermally conductive core 22C may be higher than the thermal conductivity of barrier 22B, which may also be higher than the thermal conductivity of dielectric liner 22L, recessing dielectric liner 22L or even barrier 22B may allow the sidewalls of thermally conductive core 22C or barrier 22B in the protruding portions 22P to be in direct contact with the cooling medium 54 (FIG. 4), so that better heat dissipation may be achieved.

FIG. 4 illustrates the bonding of wafer 20 (and dies 20′) with other package components to form reconstructed wafer 50 in accordance with some embodiments. The respective process is illustrated as process 208 in the process flow 200 as shown in FIG. 15. In accordance with some embodiments, the bonding is performed at wafer level, with wafer 20 being bonded to package components 120 and 320 through wafer-on-wafer bonding. In accordance with alternative embodiments, wafer 20 is singulated into discrete dies 20′ first, for example, in a die-sawing process. The resulting discrete dies 20′ may be bonded to dies 120′ and 320′ in a die-on-die bonding process, or may be bonded on wafers 120 and/or 320 through die-on-wafer bonding processes.

In accordance with some example embodiments, package components 120 and 320 have similar structures as that of wafer 20. The structures and the materials of the features in package components 120 and 320 may be found referring to the discussion of the like features in wafer 20, with the like features in package components 120 and 320 being denoted by adding number “1” or “3”) in front of the reference numbers of the corresponding features in wafer 20. For example, the substrate in wafer 20 is denoted as 24, and accordingly, the substrate in package components 120 and 320 are denoted as 124 and 324, respectively.

Package component 120 may include integrated circuit devices 126, ILD 128, contact plugs 130, interconnect structure 132, dielectric layers 138, metal lines 134, vias 136, bond film 144, bond pads 146, and bond pads 146′. Package component 320 may include integrated circuit devices 326, ILD 328, contact plugs 330, interconnect structure 332, dielectric layers 338, metal lines 334, vias 336, bond film 344, and bond pads 346. The details of these features may be similar to the corresponding features in wafer 20, and are not repeated herein. Package component 320 may also include bond pads 148 and bond film 149 at bottom in accordance with some embodiments, so that the resulting package 50′ may be electrically connected to other package components in further packaging processes, for example, when being bonded to an interposer or a package substrate.

In accordance with some embodiments, the bonding of wafer 20 to package component 120 is through hybrid bonding, which includes the bonding of bond film 44 to the bond film in package component 120 through fusion bonding (for example, with Si—O—Si bonds being formed), and the bonding of bond pads 46 to bond pads 146′ through metal-to-metal direct bonding. The bonding of package component 120 to package component 320 may also be through hybrid bonding, which includes the bonding of bond film 144 to bond film 344 through fusion bonding (for example, with Si—O—Si bonds being formed), and the bonding of bond pads 146 to bond pads 346 through metal-to-metal direct bonding.

In accordance with some embodiments, the reconstructed wafer 50 is sawed into discrete (and identical) packages 50′, with each package 50′ including one of device dies 20′, one of device dies 120′, and one of device dies 320′. The respective process is illustrated as process 210 in the process flow 200 as shown in FIG. 15. Package 50′ may then be bonded to other package components such as an interposer, a package substrate, or the like.

In accordance with some embodiments, as shown in FIG. 4, cooling medium 54 is attached to semiconductor substrate 24 as a part of the resulting package 50′, and possibly in contact with thermally conductive pillars 22. The respective process is illustrated as process 212 in the process flow 200 as shown in FIG. 15. In accordance with some embodiments, cooling medium 54 has a good thermal conductivity, which may also be higher than the thermal conductivity of silicon in accordance with some embodiments. For example, the thermal conductivity of cooling medium 54 may be higher than 4 Watts/cm-K, higher than about 10 Watts/cm-K, higher than about 20 Watts/cm-K, or higher.

In accordance with some embodiments, cooling medium 54 comprises a thermal interface material (TIM), which may be dispensed in a flowable form, and then cured into a solid form. Cooling medium 54 may also include a base material (a thermal paste or a thermal adhesive), which may include a polymer, a resin, an epoxy, and/or the like. There may also be thermally conductive particles (formed of, for example, aluminum oxide, magnesium oxide, aluminum nitride, boron nitride, or diamond powder) in the base material to improve thermal conductivity and the coefficient of thermal expansion in accordance with some embodiments.

In accordance with some embodiments, with cooling medium 54 being a thermal interface material, there may be a heat sink (heat spreader) 56 over and attached to cooling medium 54. The curing of cooling medium 54 is thus performed after heat sink 56 is attached to cooling medium 54, so that cooling medium 54 also acts as the adhesive for attaching heat sink 56. The heat sink (heat spreader) 56 may be formed of copper, nickel, silver, aluminum, or the like in accordance with some embodiments. In accordance with alternative embodiments, cooling medium 54 is formed of metal such as copper, and is a heat sink.

As shown in FIG. 4, thermally conductive pillars 22 is able to effectively conduct the heat in device die 20′ (and semiconductor substrate 24) into cooling medium 54 because of the higher thermal conductivity of thermally conductive pillars 22 than silicon. In accordance with some embodiments, thermally conductive pillars 22 have their dielectric liners 22L (FIG. 1B) recessed in the process as shown in FIG. 3, so that the thermally conductive core 22C or barrier 22B, which have higher thermal conductivity values than dielectric liners 22L, contacts cool medium 54 directly. The heat conduction (represented by arrows 58) from substrate 24 and the dielectric layers in device die 20′ to cooling medium 54 through thermally conductive pillars 22 is thus further improved.

In accordance with some embodiments, package components 120 and 320 further include thermally conductive pillars 122 and 322, respectively. Thermally conductive pillars 122 and 322 may have similar structures and formed of similar materials as that of thermally conductive pillars 22, and the details are not repeated herein.

In accordance with some embodiments, package components 120 and 320 further include (electrical) through-vias 121 and 321, which are used for conducting voltages, currents, and/or electrical signals. In accordance with some embodiments, through-vias 121 may electrically interconnect device die 20′ and device die 320′, and may electrically connect integrated circuit devices 126 to integrated circuit devices 26 and integrated circuit devices 326. Through-vias 321 may also electrically connect the integrated circuit devices 326 to package component 120. Accordingly, the integrated circuit devices 26 in device die 20′ and the integrated circuit devices 126 in device die 120′ may be electrically connected to bond pads 148 in package components 320.

In accordance with some embodiments, through-vias 121 and thermally conductive pillars 122 are formed in same manufacturing processes. Through-vias 321 and thermally conductive pillars 322 may also be formed in same manufacturing processes. Thermally conductive pillars 122 may be electrically decoupled from integrated circuit devices 26, 126, and 326. This may be achieved by using dielectric liners (such as dielectric liner 22L in FIG. 1B) to electrically insulate the thermally conductive core 122C from the respective contacting metal features. For example, either the upper end or the lower end of thermally conductive core 122C may include a horizontal portion of the dielectric liner 22L, so that thermally conductive pillars 122 are electrically decoupled from (although in physical contact with) the overlying bond pad 146 or the underlying metal line 134.

Thermally conductive pillars 22, 122, and/or 322 may be electrically floating (when the package 50′ is powered up). Alternatively, thermally conductive pillars 22, 122, and/or 322 may be terminal (end) features electrically connected to some parts of the respective integrated circuit devices 26, 126, or 326. In accordance with these embodiments, thermally conductive pillars 22, 122, and/or 322 have the same voltages as the connecting portions of the integrated circuit devices 26, 126, or 326, but there is no current flowing through the thermally conductive pillars 22, 122, and/or 322.

Alternatively, the electrical decoupling of thermally conductive core 122C may be achieved by not forming some vias/metal lines. For example, in FIG. 4, when the vias or metal lines in region 64-1 (in device die 320′), region 64-2 (in device die 120′), and/or region 64-1 (in device die 20′) are not formed, thermally conductive pillars 22, 122 and/or 322 will be electrically decoupled from integrated circuit devices 26, 126, and 326.

FIG. 4 illustrates a heat conduction path 60 including a first heat conduction path (including thermally conductive pillars 322) in device die 320′, a second heat conduction path (including thermally conductive pillars 122) in device die 120′, and a third heat conduction path (including thermally conductive pillar 22) in device die 20′. Accordingly, the heat generated in device dies 320′ and 120′ and device die 20′ may be effectively conducted into cooling medium 54.

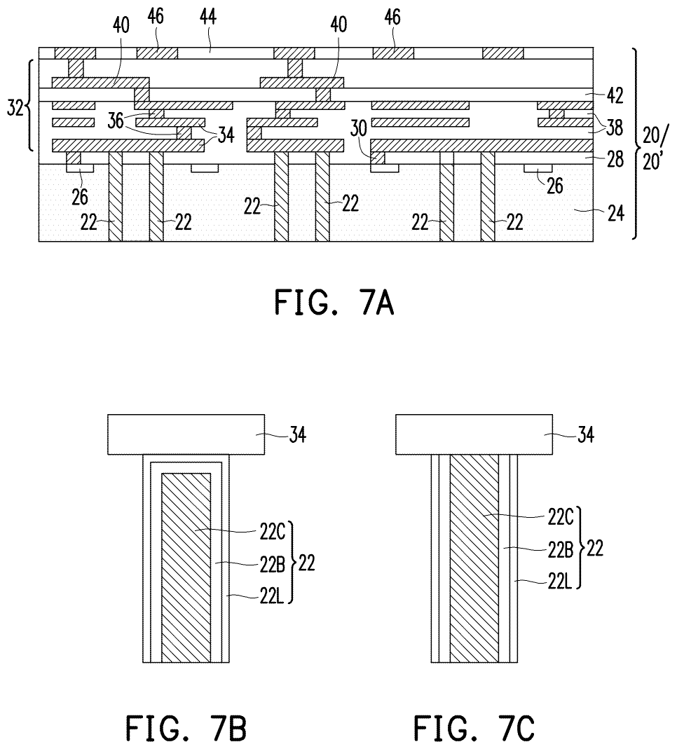

FIGS. 5, 6, 7A, 7B, 7C, 8, and 9 illustrate the cross-sectional views of intermediate stages in the formation of a package in accordance with some embodiments of the present disclosure. These processes are referred to as pillar-last processes since the thermally-conductive pillars are formed after the formation of front-side interconnect structures. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

FIG. 5 illustrates an initial structure. The initial steps of these embodiments are essentially the same as shown in FIG. 1A, except that thermally conductive pillars 22 as shown in FIGS. 1A and 1B have not been formed yet.

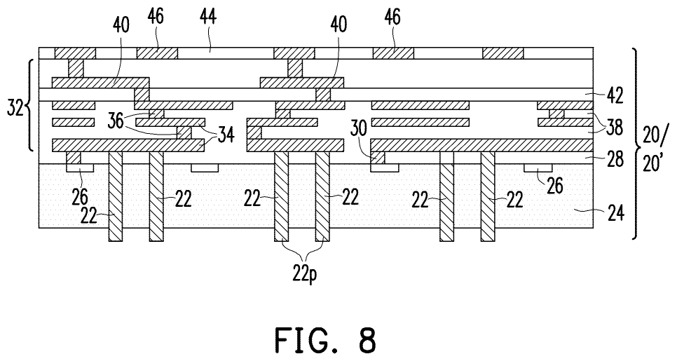

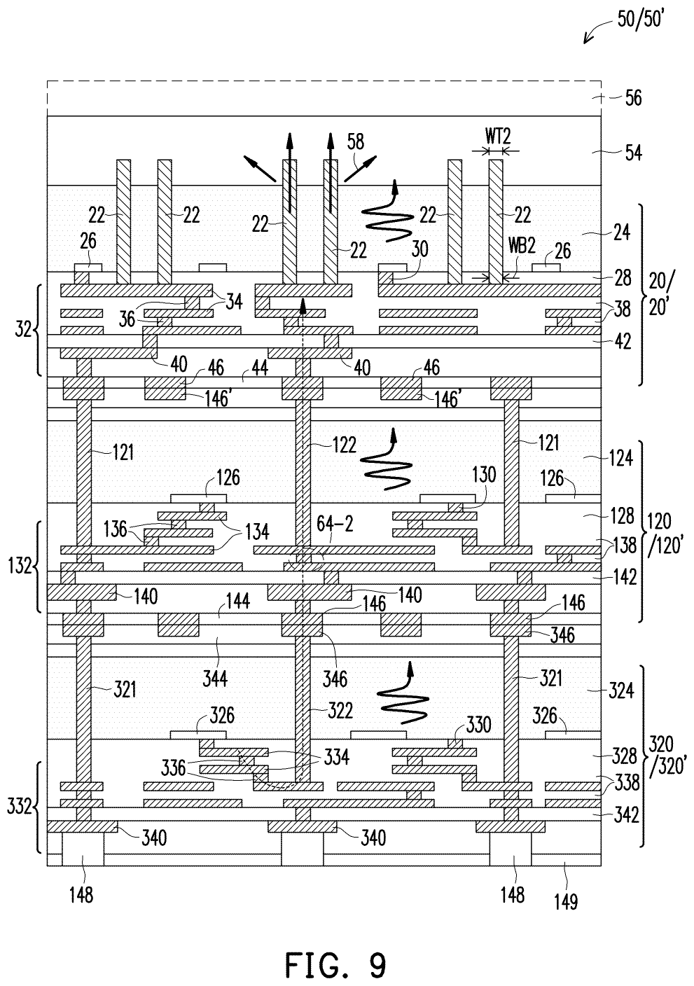

FIG. 6 illustrates a backside thinning process to thin semiconductor substrate 24. In a subsequent process, as also shown in FIG. 7A, thermally conductive pillars 22 are formed from the backside of semiconductor substrate 24. The formation process may include etching semiconductor substrate 24 and a front-side dielectric layer(s) such as ILD 28 to reveal metal lines 34, filling the openings with a dielectric liner, a barrier layer, and a core thermally conductive material, and performing a planarization process.

FIGS. 7B and 7C illustrate amplified views of thermally conductive pillars 22 in accordance with some embodiments. In accordance with some embodiments, as shown in FIG. 7B, dielectric liner 22L has a top horizontal portion separating barrier 22B and thermally conductive core 22C from the overlying metal line 34. Accordingly, barrier 22B and thermally conductive core 22C are electrically decoupled from the overlying metal line 34. In accordance with alternative embodiments, after the deposition of dielectric liner 22L and before the filling of barrier 22B and thermally conductive core 22C, an anisotropic etching process may be performed to remove the horizontal portion of the dielectric liner 22L, hence forming the structure as shown in FIG. 7C.

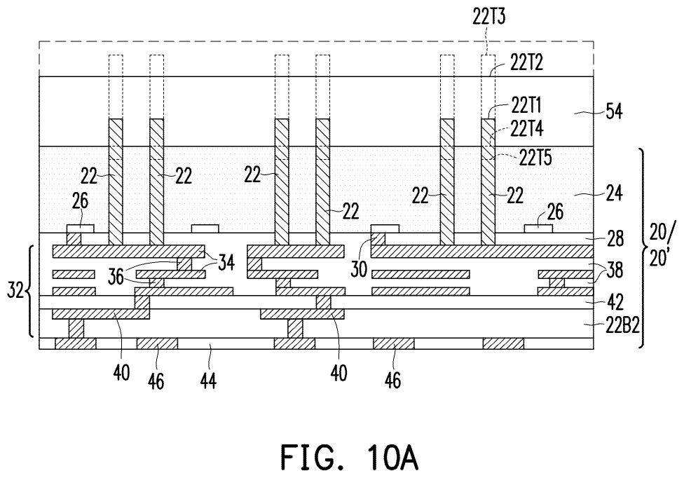

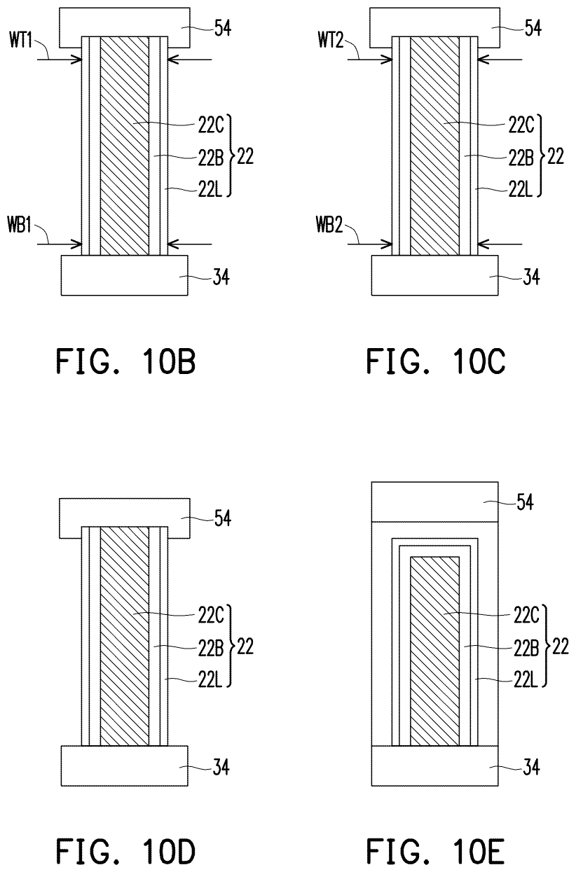

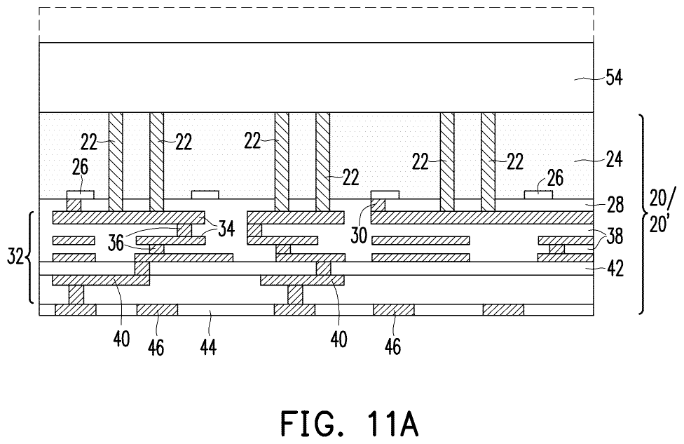

FIG. 8 illustrates the thinning of semiconductor substrate 24 from the backside. The details for the thinning process have been discussed referring to FIG. 3, and are not repeated herein. Next, as shown in FIG. 9, wafer 20 is flipped upside-down, and is bonded to package components 120 and 320 to form reconstructed wafer 50. A sawing process may then be performed to saw reconstructed wafer 50 into packages 50′. Cooling medium 54 and heat sink 56 may also be attached to form a top part of the package 50′. These structures may be the same as the package 50′ as shown in FIG. 4, except some details may be different, which difference is caused by the pillar-last process. For example, in the package 50′ as shown in FIG. 9, the bottom portions of dielectric liner 22L may have a horizontal portion, and the respective thermally conductive pillar 22 may be essentially the same as shown in FIG. 10D. In addition, the thermally conductive pillars 22 in FIG. 4 may have top width WT1 smaller than the respective bottom width WB1 due to the pillar-first process. The thermally conductive pillars 22 in FIG. 9, on the other hand, may have top width WT2 greater than the respective bottom width WB2 due to the pillar-last process.

FIG. 10A illustrates a part of the wafer 20 (and/or device die 20′) in FIG. 4 or FIG. 9 and the details of the respective thermally conductive pillars 22. In accordance with some embodiments, thermally conductive pillars 22 have protruding portions extending into cooling medium 54, as also shown in FIG. 4. The top ends of thermally conductive pillars 22 are shown as top ends 22T1. In accordance with alternative embodiments, the top ends 22T2 of thermally conductive pillars 22 are coplanar with the top surface of cooling medium 54. In accordance with yet alternative embodiments, thermally conductive pillars 22 extend into cooling medium 54, and the top ends 22T3 of thermally conductive pillars 22 are higher than the top surface of cooling medium 54. In accordance with yet alternative embodiments, the top ends 22T4 of thermally conductive pillars 22 are coplanar with the back surface of semiconductor substrate 24. In accordance with yet alternative embodiments, the top ends 22T5 of thermally conductive pillars 22 are embedded in semiconductor substrate 24. In accordance with these embodiments, the horizontal portions of dielectric liners 22L may exist, as shown in FIG. 10E since thermally conductive pillars 22 are not polished.

FIGS. 10B, 10C, 10D, and FIG. 10E illustrate the amplified views of thermally conductive pillars 22 and their overlying and underlying features in accordance with some embodiments. The dashed rectangles represent that the thermally conductive core 22C may (or may not) extend into cooling medium 54. As shown in FIG. 10B, the thermally conductive core 22C of thermally conductive pillar 22 is in physical contact with both of cooling medium 54 and metal line 34. In FIG. 10B, due to the pillar-first process, the top width WT1 of thermally conductive pillar 22 is smaller than the respective bottom width TB1.

FIGS. 10C and 10D illustrate the possible structures of thermally conductive pillars 22 and their overlying and underlying features formed through a pillar-last process in accordance with some embodiments. As shown in FIG. 10C, the thermally conductive core 22C of thermally conductive pillar 22 is in physical contact with both of cooling medium 54 and metal line 34. To form this structure, a liner-opening process is performed to remove the horizontal portions of the dielectric liner 22L. FIG. 10D illustrates the structure in which the dielectric liner 22L has a horizontal portion separating the thermally conductive core 22C of thermally conductive pillar 22 from metal line 34. In FIGS. 10C and 10D, due to the pillar-last process, the top width WT2 of thermally conductive pillar 22 are greater than the respective bottom widths TB2.

FIG. 10E illustrates the thermally conductive pillar 22 that is spaced apart from cooling medium 54 by a portion of semiconductor substrate 24 in accordance with some embodiments. The thermally conductive pillar 22 has the top end 22T5 as shown in FIG. 10A.

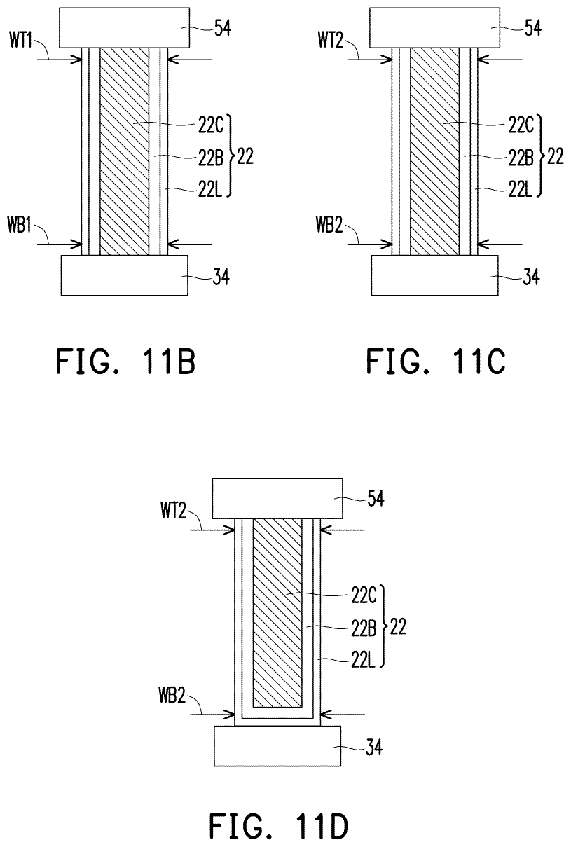

FIG. 11A illustrates an amplified structure of wafer 20 (and device die 20′) in accordance with alternative embodiments. These embodiments are similar to the embodiments in FIG. 10A, except that the top surfaces of thermally conductive pillars 22 are coplanar with the top surface of cooling medium 54.

FIGS. 11B, 11C, and 11D illustrate the amplified views of the thermally conductive pillars 22 corresponding to FIG. 11A. FIG. 11B illustrates the structure formed through the pillar-first process. In FIG. 11B, due to the pillar-first process, the top width WT1 of thermally conductive pillar 22 is smaller than the respective bottom width TB1. FIGS. 11C and 11D illustrate the possible structures that may be formed through pillar-last processes. In FIGS. 11C and 11D, due to the pillar-last process, the top width WT2 of thermally conductive pillars 22 are greater than the respective bottom widths TB2.

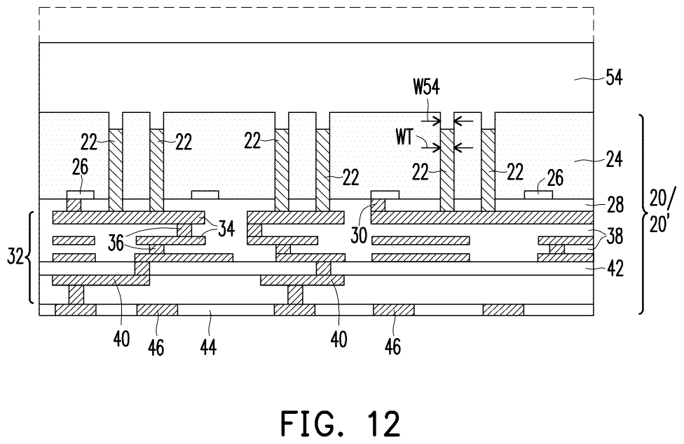

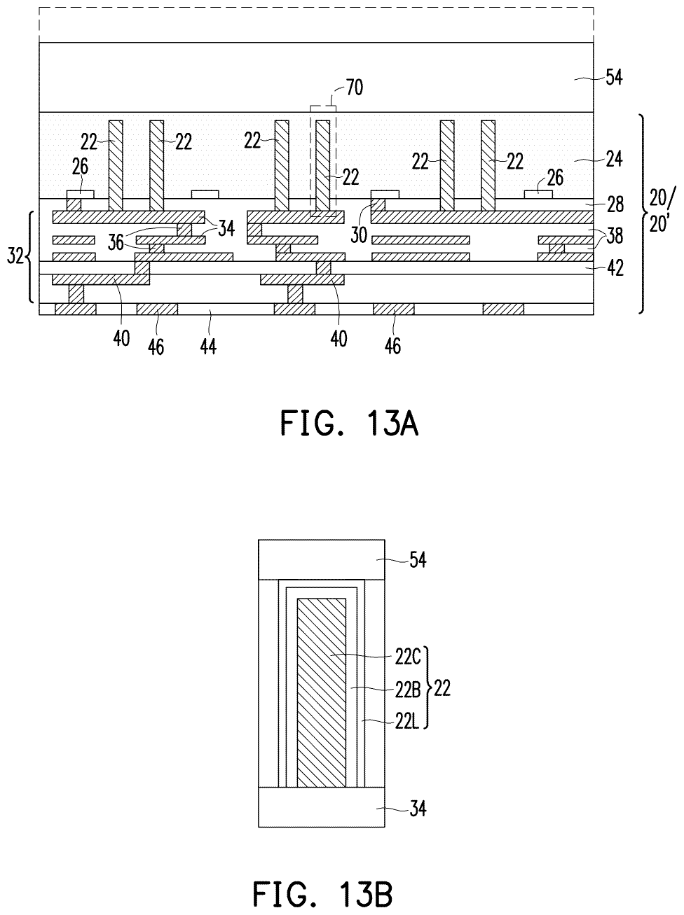

FIG. 12 illustrates wafer 20 (and device die 20′) in accordance with alternative embodiments. In accordance with these embodiments, the backside thinning process (FIG. 2) is finished before the thermally conductive pillars 22 are exposed. Accordingly, a portion of the semiconductor substrate 24 would cover the embedded thermally conductive pillars 22. Next, an etching process is performed to remove some portions of the semiconductor substrate 24 covering the embedded thermally conductive pillars 22. The dielectric liners 22L will thus be exposed. In accordance with some embodiments, the exposed horizontal portion of dielectric liner 22L are etched to reveal the underlying horizontal portion of barrier 22B (refer to FIG. 13B for reference). The exposed horizontal portion of barrier 22B may also be etched to expose the underlying thermally conductive core 22C, or may not be etched. In accordance with alternative embodiments, the exposed horizontal portion of dielectric liner 22L are not etched.

The cooling medium 54 may then be dispensed, and fills the openings formed by etching semiconductor substrate 24. In accordance with some embodiments in which dielectric liner 22L is not etched, the cooling medium 54 is in contact with the horizontal portion of dielectric liner 22L. The horizontal portion of dielectric liner 22L thus electrically decouple the thermally conductive core 22C from cooling medium 54. In accordance with some embodiments in which dielectric liner 22L is etched, the cooling medium 54 is in contact with the horizontal portion of barrier 22B (when barrier 22B is not etched) or the thermally conductive core 22C.

FIGS. 13A and 13B illustrate the wafer 20 (and device die 20′) and the amplified thermal conductive pillars 22, respectively. The structure shown in FIG. 13B is in the region 70 in FIG. 13A. FIGS. 13A and 13B illustrate that thermally conductive pillars 22 are separated from cooling medium 54 by a portion of semiconductor substrate 24.

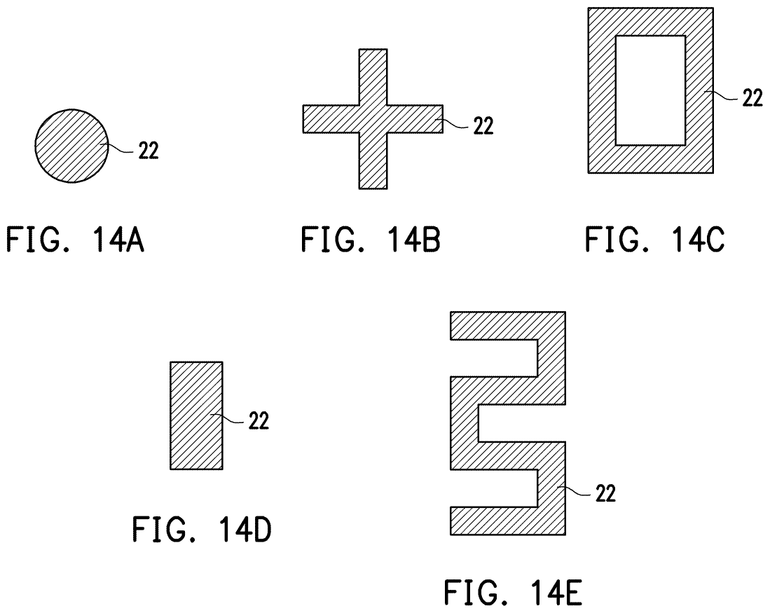

FIGS. 14A, 14B, 14C, 14D, and 14E illustrate the top views of thermally conductive pillars 22 in accordance with various embodiments. In these embodiments, the shapes of the thermally conductive pillars 22 are selected so that the surface areas (the total lengths of the peripheral) are large, and hence the efficiency in the heat conductive is improved. FIG. 14A illustrates that the thermally conductive pillar 22 has a circular top-view shape. FIG. 14B illustrates that the thermally conductive pillar 22 has a cross top-view shape. FIG. 14C illustrates the thermally conductive pillar 22 has a ring-shaped top-view shape. FIG. 14D illustrates that the thermally conductive pillar 22 has a rectangular top-view shape. FIG. 14E illustrates that the thermally conductive pillar 22 includes a plurality of sections extending back-and-forth.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming thermally conductor pillars that have a high thermal conductivity to conduct heat to a cooling medium and a heat sink, better heat dissipation may be achieved.

In accordance with some embodiments of the present disclosure, a method comprises forming a first device die comprising forming integrated circuits on a first semiconductor substrate; and forming a thermally conductive pillar extending into the first semiconductor substrate; and attaching a cooling medium over and contacting the first semiconductor substrate to form a package, wherein the cooling medium is thermally coupled to the thermally conductive pillar. In an embodiment, the attaching the cooling medium comprises dispensing the cooling medium in a flowable form; and curing to solidify the cooling medium.

In an embodiment, the method further comprises attaching a heat sink to the cooling medium, wherein the thermally conductive pillar penetrates through the cooling medium to contact the heat sink. In an embodiment, the thermally conductive pillar penetrates through the first semiconductor substrate, and the thermally conductive pillar is in physical contact with the cooling medium. In an embodiment, the method further comprises polishing the first semiconductor substrate to expose a surface of the thermally conductive pillar, wherein a first top surface of the thermally conductive pillar and a second top surface of the first semiconductor substrate are coplanar.

In an embodiment, the method further comprises, after the polishing, recessing the first semiconductor substrate so that a protruding portion of the thermally conductive pillar protrudes out of the first semiconductor substrate to extend into the cooling medium. In an embodiment, the thermally conductive pillar is electrically floating. In an embodiment, the method further comprises bonding a second device die to the first device die, with the second device die being an additional part of the package, wherein the second device die comprises a second semiconductor substrate; and an additional thermally conductive pillar penetrating through the second semiconductor substrate, wherein the additional thermally conductive pillar is electrically and thermally coupled to the thermally conductive pillar.

In an embodiment, the forming the thermally conductive pillar comprises etching the first semiconductor substrate to form an opening; depositing a dielectric liner into the opening; and depositing a metallic material into the opening and on the dielectric liner. In an embodiment, the method further comprises, after the depositing the dielectric liner and before depositing the metallic material, performing an anisotropic etching process on the dielectric liner.

In accordance with some embodiments of the present disclosure, a structure comprises a first device die comprising a first semiconductor substrate; integrated circuits on the first semiconductor substrate; dielectric layers underlying the first semiconductor substrate; and a thermally conductive pillar extending into the first semiconductor substrate; and a cooling medium over and contacting the first semiconductor substrate, wherein the cooling medium is in contact with the thermally conductive pillar. In an embodiment, the cooling medium comprises an adhesive comprising a polymer; and thermally conductive filler particles in the polymer. In an embodiment, the thermally conductive pillar is in contact with the cooling medium.

In an embodiment, the thermally conductive pillar extends into the cooling medium. In an embodiment, the structure further comprises a heat sink, wherein the thermally conductive pillar penetrates through the cooling medium to contact the heat sink. In an embodiment, the thermally conductive pillar is electrically floating.

In an embodiment, the structure further comprises a second device die bonding to the first device die, and the second device die comprises a second semiconductor substrate; and an additional thermally conductive pillar penetrating through the second semiconductor substrate, wherein the additional thermally conductive pillar is electrically and thermally coupled to the thermally conductive pillar.

In accordance with some embodiments of the present disclosure, a structure comprises a device die comprising a semiconductor substrate; a plurality of dielectric layers underlying the semiconductor substrate; a thermally conductive pillar penetrating through the semiconductor substrate, wherein the thermally conductive pillar extends into one of the plurality of dielectric layers; and a thermal interface material over and contacting the semiconductor substrate, wherein the thermally conductive pillar is in physical contact with the thermal interface material. In an embodiment, the thermally conductive pillar is electrically floating. In an embodiment, the thermally conductive pillar comprises a metal core, and the metal core is in physical contact with the thermal interface material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first device die comprising:
forming integrated circuits on a first semiconductor substrate; and
forming a thermally conductive pillar extending into the first semiconductor substrate; and
attaching a cooling medium over and contacting the first semiconductor substrate to form a package, wherein the cooling medium is thermally coupled to the thermally conductive pillar.

2. The method of claim 1, wherein the attaching the cooling medium comprises:
dispensing the cooling medium in a flowable form; and
curing to solidify the cooling medium.

3. The method of claim 2 further comprising attaching a heat sink to the cooling medium, wherein the thermally conductive pillar penetrates through the cooling medium to contact the heat sink.

4. The method of claim 1, wherein the thermally conductive pillar penetrates through the first semiconductor substrate, and the thermally conductive pillar is in physical contact with the cooling medium.

5. The method of claim 4 further comprising polishing the first semiconductor substrate to expose a surface of the thermally conductive pillar, wherein a first top surface of the thermally conductive pillar and a second top surface of the first semiconductor substrate are coplanar.

6. The method of claim 4 further comprising, after the polishing, recessing the first semiconductor substrate so that a protruding portion of the thermally conductive pillar protrudes out of the first semiconductor substrate to extend into the cooling medium.

7. The method of claim 1, wherein the thermally conductive pillar is electrically floating.

8. The method of claim 1 further comprising bonding a second device die to the first device die, with the second device die being an additional part of the package, wherein the second device die comprises:
a second semiconductor substrate; and
an additional thermally conductive pillar penetrating through the second semiconductor substrate, wherein the additional thermally conductive pillar is electrically and thermally coupled to the thermally conductive pillar.

9. The method of claim 1, wherein the forming the thermally conductive pillar comprises:
etching the first semiconductor substrate to form an opening;
depositing a dielectric liner into the opening; and
depositing a metallic material into the opening and on the dielectric liner.

10. The method of claim 9 further comprising, after the depositing the dielectric liner and before depositing the metallic material, performing an anisotropic etching process on the dielectric liner.

11. A structure comprising:
a first device die comprising:
a first semiconductor substrate;
integrated circuits on the first semiconductor substrate;
dielectric layers underlying the first semiconductor substrate; and
a thermally conductive pillar extending into the first semiconductor substrate; and
a cooling medium over and contacting the first semiconductor substrate, wherein the cooling medium is in contact with the thermally conductive pillar.

12. The structure of claim 11, wherein the cooling medium comprises an adhesive comprising:
a polymer; and
thermally conductive filler particles in the polymer.

13. The structure of claim 11, wherein the thermally conductive pillar is in contact with the cooling medium.

14. The structure of claim 13, wherein the thermally conductive pillar extends into the cooling medium.

15. The structure of claim 14 further comprising a heat sink, wherein the thermally conductive pillar penetrates through the cooling medium to contact the heat sink.

16. The structure of claim 11, wherein the thermally conductive pillar is electrically floating.

17. The structure of claim 11 further comprising a second device die bonding to the first device die, and the second device die comprises:
a second semiconductor substrate; and
an additional thermally conductive pillar penetrating through the second semiconductor substrate, wherein the additional thermally conductive pillar is electrically and thermally coupled to the thermally conductive pillar.

18. A structure comprising:
a device die comprising:
a semiconductor substrate;
a plurality of dielectric layers underlying the semiconductor substrate;
a thermally conductive pillar penetrating through the semiconductor substrate, wherein the thermally conductive pillar extends into one of the plurality of dielectric layers; and
a thermal interface material over and contacting the semiconductor substrate, wherein the thermally conductive pillar is in physical contact with the thermal interface material.

19. The structure of claim 18, wherein the thermally conductive pillar is electrically floating.

20. The structure of claim 18, wherein the thermally conductive pillar comprises a metal core, and the metal core is in physical contact with the thermal interface material.
